(19) United States
(12) Patent Application Publication
(10) Pub. No.: US 2024/0355802 A1
(43) Pub. Date: Oct. 24, 2024

(54) SEMICONDUCTOR PACKAGE

(71) Applicant: SAMSUNG ELECTRONICS CO., LTD., Suwon-Si (KR)

(72) Inventors: Chengtar WU, Suwon-si (KR); Jongkook Kim, Suwon-si (KR)

(21) Appl. No.: 18/384,912

(22) Filed: Oct. 30, 2023

(30) Foreign Application Priority Data
Apr. 19, 2023 (KR) 10-2023-0051501

(51) Int. Cl. H01L 25/18; H01L 23/00; H01L 23/31; H01L 23/48; H01L 23/538; H10B 80/00

(52) U.S. Cl. CPC H01L 25/18; H01L 23/3157; H01L 23/481; H01L 23/5381; H01L 23/5383; H01L 24/08; H01L 24/16; H01L 24/32; H01L 24/73; H01L 28/60; H10B 80/00; H01L 2224/08145; H01L 2224/08235; H01L 2224/16145; H01L 2224/32145; H01L 2224/73204

(57) ABSTRACT

A three-dimensional integrated circuit structure includes: a first semiconductor die; and a second semiconductor die disposed on the first semiconductor die, wherein the first semiconductor die includes: a plurality of through-silicon vias (TSV); and a plurality of integrated stack capacitor (ISC) chips, wherein each of the plurality of ISC chips is disposed between adjacent through-silicon vias among the plurality of through-silicon vias.

### CROSS-REFERENCE TO RELATED APPLICATION

This application claims priority under 35 U.S.C. § 119 to Korean Patent Application No. 10-2023-0051501 filed in the Korean Intellectual Property Office on Apr. 19, 2023, the disclosure of which is incorporated by reference herein in its entirety.

### TECHNICAL FIELD

The present inventive concept relates to a semiconductor package.

### DISCUSSION OF THE RELATED ART

The semiconductor industry may increase integration density of devices so that more passive or active devices may be integrated in a given area. In accordance with this trend of increased integration density, the integration of semiconductor chips may increase, and high-performance circuits with high-speed digital signals may be included in semiconductor packages.

A power integrity (PI) characteristic is desirable in the semiconductor package including the high-performance circuit, and capacitance of a capacitor may be implemented with a higher capacitance to increase the power integrity (PI).

However, a multilayer ceramic capacitor (MLCC), a land side capacitor (LSC), or an individual integrated stack capacitor (ISC) mounted on a conventional semiconductor package has capacitance that may be insufficient when compared to the capacitance used by the high-performance circuit, and may be disposed at a distance apart from the high-performance circuits. Therefore, even if the MLCC, the LSC, or the ISC is disposed in the semiconductor package that includes the high-performance circuit, it may be difficult to increase the power integrity (PI) of the semiconductor package that includes the high-performance circuit.

Therefore, semiconductor package technology has been under development to increase the power integrity (PI) of a semiconductor package including a high-performance circuit.

### SUMMARY

According to an embodiment of the present inventive concept, a three-dimensional integrated circuit structure includes: a first semiconductor die; and a second semiconductor die disposed on the first semiconductor die, wherein the first semiconductor die includes: a plurality of through-silicon vias (TSV); and a plurality of integrated stack capacitor (ISC) chips, wherein each of the plurality of ISC chips is disposed between adjacent through-silicon vias among the plurality of through-silicon vias.

According to an embodiment of the present inventive concept, a three-dimensional integrated circuit structure includes: a redistribution structure; a first semiconductor die disposed on the redistribution structure; an interconnection structures disposed on the first semiconductor die; and a second semiconductor die disposed on the interconnection structure, wherein the first semiconductor die includes: a plurality of through-silicon vias (TSV); and a plurality of integrated stack capacitor (ISC) chips, wherein each of the plurality of integrated stack capacitor chips is disposed between neighboring through-silicon vias among the plurality of through-silicon vias.

According to an embodiment of the present inventive concept, a semiconductor package includes: a substrate; a three-dimensional integrated circuit structure disposed on the substrate; a semiconductor structure disposed adjacent to the three-dimensional integrated circuit structure on the substrate; and a bridge structure disposed in the substrate and electrically connecting the three-dimensional integrated circuit structure and the semiconductor structure to each other, wherein the three-dimensional integrated circuit structure includes: a first semiconductor die; and a second semiconductor die disposed on the first semiconductor die, wherein the first semiconductor die includes: a plurality of through-silicon vias (TSV); and a plurality of integrated stack capacitor (ISC) chips, wherein each of the plurality of integrated stack capacitor chips is disposed between adjacent through-silicon vias among the plurality of through-silicon vias.

### BRIEF DESCRIPTION OF THE DRAWINGS

FIG. 1 illustrates a cross-sectional view of a 3D integrated circuit (3D IC) structure according to an embodiment of the present inventive concept.

FIG. 2 illustrates a cross-sectional view of a portion of the inside of an ISC chip according to an embodiment of the present inventive concept.

FIG. 3 illustrates a cross-sectional view of a 3D integrated circuit (3D IC) structure according to an embodiment of the present inventive concept.

FIG. 4 illustrates a cross-sectional view of a step of providing a first semiconductor die including ISC chips and TSVs, in a manufacturing method of a 3D IC structure according to an embodiment of the present inventive concept.

FIG. 5 illustrates a cross-sectional view of a step of forming a redistribution structure on a first semiconductor die, in a manufacturing method of a 3D IC structure according to an embodiment of the present inventive concept.

FIG. 6 illustrates a cross-sectional view of a step of forming an external connection structure on a redistribution structure, in a manufacturing method of a 3D IC structure according to an embodiment of the present inventive concept.

FIG. 7 illustrates a cross-sectional view of a step of bonding a carrier under an external connection structure, in a manufacturing method of a 3D IC structure according to an embodiment of the present inventive concept.

FIG. 8 illustrates a cross-sectional view of a step of removing an upper surface of a first semiconductor die, in a manufacturing method of a 3D IC structure according to an embodiment of the present inventive concept.

FIG. 9 illustrates a cross-sectional view of a step of mounting a second semiconductor die on a first semiconductor die by flip-chip bonding, in a manufacturing method of a 3D IC structure according to an embodiment of the present inventive concept. FIG. 9 and FIG. 10 illustrate cross-sectional views of steps in the manufacturing method of the 3D IC structure of FIG. 1 according to an embodiment of the present inventive concept.

FIG. 10 illustrates a cross-sectional view of a step of forming an insulating member between a first semiconductor die and a second semiconductor die, in a manufacturing method of a 3D IC structure according to an embodiment of the present inventive concept.

FIG. 11 illustrates a cross-sectional view of a step of mounting a second semiconductor die on a first semiconductor die by hybrid bonding, in a manufacturing method of a 3D IC structure according to an embodiment of the present inventive concept. FIG. 11 illustrates a cross-sectional view of steps of the manufacturing method of the 3D IC structure of FIG. 3 according to an embodiment of the present inventive concept.

FIG. 12 illustrates a cross-sectional view of a step of molding a second semiconductor die on a first semiconductor die, in a manufacturing method of a 3D IC structure according to an embodiment of the present inventive concept.

FIG. 13 illustrates a cross-sectional view of a step of planarizing a molding material, in a manufacturing method of a 3D IC structure according to an embodiment of the present inventive concept.

FIG. 14 illustrates a cross-sectional view of a step of de-bonding a carrier from an external connection structure, in a manufacturing method of a 3D IC structure according to an embodiment of the present inventive concept.

FIG. 15 illustrates a cross-sectional view of a semiconductor package that includes a 3D IC structure according to an embodiment of the present inventive concept.

FIG. 16 illustrates a cross-sectional view of a step of providing a substrate including a cavity, in a manufacturing method of a 3D IC structure according to an embodiment of the present inventive concept.

FIG. 17 illustrates a cross-sectional view of a step of mounting a bridge structure in a cavity of a substrate, in a manufacturing method of a 3D IC structure according to an embodiment of the present inventive concept.

FIG. 18 illustrates a cross-sectional view of a step of molding a bridge structure within a cavity of a substrate, in a manufacturing method of a 3D IC structure according to an embodiment of the present inventive concept.

FIG. 19 illustrates a cross-sectional view of a step of forming a connection structure on a substrate and a molding material, in a manufacturing method of a semiconductor package according to an embodiment of the present inventive concept.

FIG. 20 illustrates a cross-sectional view of a step of mounting a 3D IC structure and a semiconductor structure on a connection structure, in a manufacturing method of a semiconductor package according to an embodiment of the present inventive concept.

FIG. 21 illustrates a cross-sectional view of a step of under-filling a 3D IC structure and a semiconductor structure on a connection structure, in a manufacturing method of a semiconductor package according to an embodiment of the present inventive concept.

### DETAILED DESCRIPTION OF THE EMBODIMENTS

The embodiments of the present inventive concept will be described more fully hereinafter with reference to the accompanying drawings. However, the present inventive concept may be modified in various different forms, and is not limited to the embodiments provided herein.

The drawings and description are to be regarded as illustrative in nature and not restrictive. Like reference numerals may designate like elements throughout the specification and drawings, and thus their descriptions may be omitted.

In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

Throughout this specification and the claims that follow, when it is described that an element is “coupled or connected” to another element, the element may be “directly coupled or connected” to the other element or “indirectly coupled or connected” to the other element through a third element.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present between the element and the other element. Further, in the specification, the word “on” or “above” may mean disposed on or below the object portion, and might not necessarily mean disposed on the upper side of the object portion based on a gravitational direction.

Further, throughout the specification, the phrase “in a plan view” or “on a plane” means viewing a target portion from the top unless indicated otherwise, and the phrase “in a cross-sectional view” or “on a cross-section” means viewing a cross-section formed by vertically cutting a target portion from the side.

Hereinafter, a 3D IC structure and a semiconductor package including the same according to an embodiment of the present inventive concept will be described with reference to the accompanying drawings.

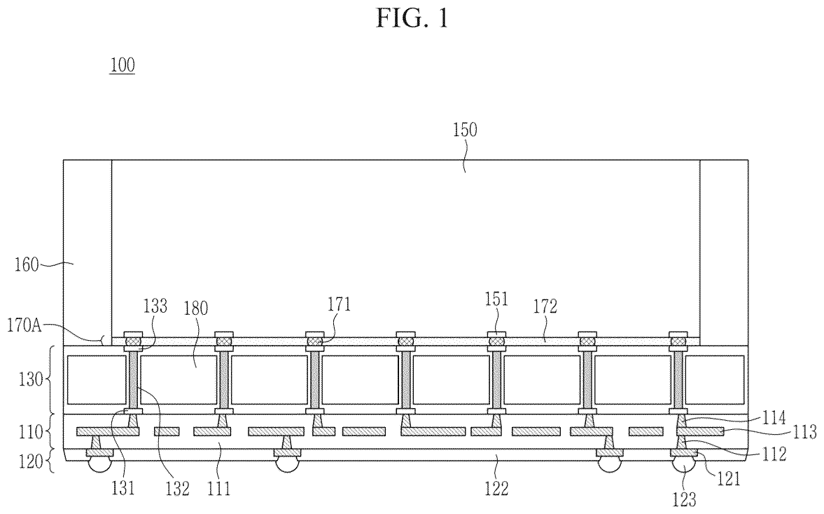

FIG. 1 illustrates a cross-sectional view of a 3D integrated circuit (3D IC) structure that includes a first semiconductor die 130 and a second semiconductor die 150. The first semiconductor die 130 may include integrated stack capacitor (ISC) chips 180 and through-silicon vias (TSV) 132, and the second semiconductor die 150 may be disposed on the first semiconductor die 130. The first semiconductor die 130 and the second semiconductor die 150 are electrically and physically connected to each other by a connection member 171.

Referring to FIG. 1, a 3D IC structure 100 may include a redistribution structure 110, a first semiconductor die 130, a second semiconductor die 150, a molding material 160, an interconnection structure 170A, and an external connection structure 120.

The redistribution structure 110 may include a dielectric material layer 111, and first redistribution vias 112, first redistribution lines 113, and second redistribution vias 114 within the dielectric material layer 111. In an embodiment of the present inventive concept, a redistribution structure that includes fewer or greater numbers of redistribution lines and redistribution vias is within the scope of the present inventive concept.

The dielectric material layer 111 may protect and insulate the first redistribution vias 112, the first redistribution lines 113, and the second redistribution vias 114. The first semiconductor die 130 may be disposed on an upper surface of the dielectric material layer 111, and the external connection structure 120 may be disposed on a lower surface of the dielectric material layer 111.

The first redistribution via 112 may be disposed between the first redistribution line 113 and a conductive pad 121 of the external connection structure 120. The first redistribution via 112 may electrically connect the first redistribution line 113 and the conductive pad 121 to each other in a vertical direction. The first redistribution line 113 may be disposed between the first redistribution via 112 and the second redistribution via 114. The first redistribution line 113 may electrically connect the first redistribution via 112 and the second redistribution via 114 to each other in a horizontal direction. The second redistribution via 114 may be disposed between the first redistribution line 113 and a lower connection pad 131 of the first semiconductor die 130. The second redistribution via 114 may electrically connect the first redistribution line 113 and the lower connection pad 131 of the first semiconductor die 130 to each other in a vertical direction. For example, the second redistribution via 114 may be directly connected to the lower connection pad 131 of the first semiconductor die 130, with no connection member. In the present embodiment, a width of an uppermost portion of each of the first redistribution via 112 and the second redistribution via 114 may be smaller than that of a lowermost portion thereof. For example, each of the first redistribution via 112 and the second redistribution via 114 may have an inverted tapered shape.

The first semiconductor die 130 may include the ISC chips 180, the TSVs 132, the lower connection pads 131, and the upper connection pads 133. The ISC chip 180 may include a capacitor structure 188 that continuously extends in a vertical cylindrical structure in which tens of thousands or more are disposed and includes a lower electrode 181, a dielectric film 182, and an upper electrode 183.

In the present embodiment, each of the ISC chips 180 may be disposed between adjacent TSVs of the TSVs 132. In the present embodiment, each of the TSVs 132 and each of the ISC chips 180 may be alternately disposed with each other. In the present embodiment, a distance between each of the TSVs 132 and the ISC chip 180, which are adjacent to each TSV, may be smaller than a width of each TSV 132 in the horizontal direction.

In the present embodiment, the first semiconductor die 130 might not include semiconductor chips other than the ISC chips 180. In the present embodiment, the ISC chips 180 may be disposed in most regions of the first semiconductor die 130 to have a capacitance density required in the second semiconductor die 150, while other semiconductor chips (for example, a logic chip, a memory, a communication chip, a controller, a sensor, a codec, and the like) may be disposed in some remaining regions of the first semiconductor die 130.

The ISC chip 180 according to an embodiment of the present inventive concept may suppress power noise in a high frequency band of hundreds of MHz, and has a much larger capacitance density than a multilayer ceramic capacitor (MLCC) or an LSC. The ISC chips 180 may be disposed in the first semiconductor die 130 below the 3D IC structure to increase the power integrity (PI) of the semiconductor package.

The TSV 132 may be disposed between the lower connection pad 131 and an upper connection pad 133. The TSV 132 may electrically connect the lower connection pad 131 and the upper connection pad 133 to each other. In an embodiment of the present inventive concept, the TSV 132 may include at least one of tungsten, aluminum, copper, and an alloy thereof. Each of the lower connection pad 131 and the upper connection pad 133 may include, for example, at least one of copper, aluminum, silver, tin, gold, nickel, lead, titanium, and an alloy thereof.

The second semiconductor die 150 may include second semiconductor chips. In the present embodiment, the second semiconductor chip may be a semiconductor chip that includes a high-performance circuit. In the present embodiment, the second semiconductor chip may include a system on chip (SOC). In the present embodiment, the second semiconductor chip may include at least one of, for example, a central processing unit (CPU), a graphics processing unit (GPU), a memory, a controller, a codec, a sensor, and a communication unit.

In the 3D IC structure 100 according to an embodiment of the present inventive concept, the ISC chips 180 and the TSVs 132 are disposed in the first semiconductor die 130, and the second semiconductor chip including the high-performance circuit is disposed on the second semiconductor die 150 that is disposed on the first semiconductor die 130, so that a distance between the ISC chips 180 and the second semiconductor chip including the high-performance circuit requiring the high-density capacitance may be reduced. In addition, since the TSVs 132 are disposed in the first semiconductor die 130 and connected to the second semiconductor die 150, it is possible to increase speed of reception and response of signals and to increase power between the ISC chips 180 and the second semiconductor chips including high-performance circuits.

The molding material 160 may mold the second semiconductor die 150 on the first semiconductor die 130. For example, the molding material 160 may be disposed on the first semiconductor die 130 and may at least partially surround the second semiconductor die 150. The molding material 160 may be made of a thermosetting resin such as an epoxy resin. In an embodiment of the present inventive concept, the molding material 160 may be an epoxy molding compound (EMC).

The interconnection structure 170A may be disposed between the first semiconductor die 130 and the second semiconductor die 150. The interconnect structure 170A may include connection members 171 and insulating members 172. The connection member 171 may electrically connect the upper connection pad 133 of the first semiconductor die 130 and a connection pad 151 of the second semiconductor die 150 to each other. In the present embodiment, the connection member 171 may include, for example, micro-bumps. The insulating member 172 may at least partially surround and protect the connection member 171 that is disposed between the first semiconductor die 130 and the second semiconductor die 150. In the present embodiment, the insulating member 172 may include, for example, a molded under-fill (MUF). In the present embodiment, the insulating member 172 may include, for example, a non-conductive film (NCF).

The external connection structure 120 may be disposed on the lower surface of the redistribution structure 110. The external connection structure 120 may include conductive pads 121, an insulating layer 122, and external connection members 123. The conductive pad 121 may be electrically connected to the first redistribution via 112 of the redistribution structure 110 and the external connection member 123. The insulating layer 122 may include a plurality of openings for soldering. The insulating layer 122 prevents the external connection member 123 from being short-circuited. The external connection member 123 may be disposed in the opening of the insulating layer 122, and may electrically connect the 3D IC structure 100 to an external device.

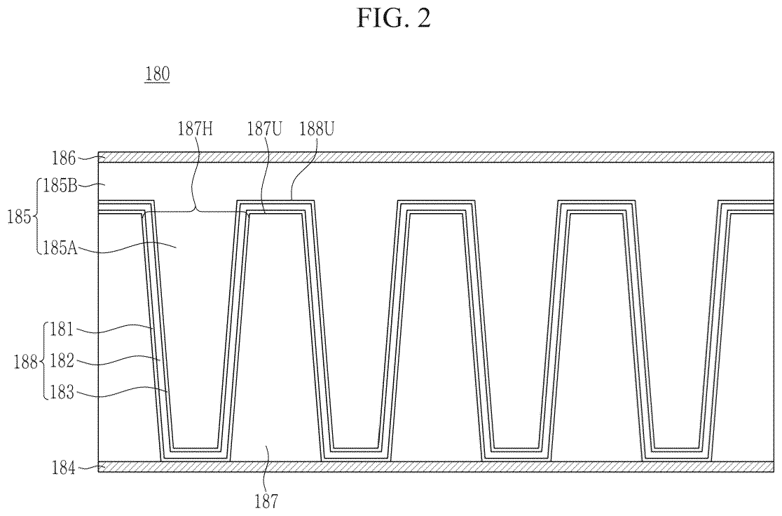

FIG. 2 illustrates a cross-sectional view of a portion of the inside of the ISC chip 180 according to an embodiment of the present inventive concept.

Referring to FIG. 2, the ISC chip 180 may include a capacitor structure 188 including a lower electrode 181, a dielectric film 182, and an upper electrode 183. The ISC chip 180 may further include a lower plate layer 184, a conductive interconnection member 185, and an upper plate layer 186.

The lower plate layer 184 may be disposed under a lower surface of the capacitor structure 188 and a lower surface of an insulating layer 187, and may be electrically connected to the lower electrode 181 of the capacitor structure 188. In the present embodiment, the lower plate layer 184 may include TiN.

The capacitor structure 188 may include the lower electrode 181, the dielectric film 182, and the upper electrode 183. The capacitor structure 188 may be disposed on the lower plate layer 184, and may be disposed within the insulating layer 187. Through-holes 187H may be formed in the insulating layer 187, and the capacitor structure 188 may be continuously formed in the through-holes 187H and on the insulating layer 187. For convenience, in the embodiment of FIG. 2, four through-holes 187H in the insulating layer 187 are shown, but the present inventive concept is not limited thereto. For example, the insulating layer 187 may include tens of thousands of through-holes 187H, and the capacitor structure 188 may be continuously formed in the tens of thousands of through-holes 187H and on the insulating layer 187 around the through-holes 187H. In the present embodiment, in a plan view, the through-holes 187H in insulating layer 187 may have a circular shape. In an embodiment of the present inventive concept, in a plan view, the through-holes 187H in the insulating layer 187 may have an elliptical or polygonal shape.

The capacitor structure 188 according to an embodiment of the present inventive concept is formed in the vertical direction along an inner surface of each of the through-holes 187H that are in the insulating layer 187, and continuously extends in the horizontal direction along an upper surface 187U of the insulating layer 187 around or adjacent to each through-hole 187H, so that the capacitor structure 188 has a three-dimensional capacitor structure in horizontal and vertical directions. Accordingly, the capacitor structure 188 according to an embodiment of the present inventive concept may have a high density capacitance compared to a conventional multilayer ceramic capacitor (MLCC) or LSC.

The lower electrode 181 may continuously and conformally extend along the inside of the through-holes 187H (e.g., an upper surface of the lower plate layer 210 and an inner surface of the through-hole 187H) and along the upper surface 187U of the insulating layer 187 around or adjacent to the through-holes 187H. The lower electrode 181 may contact the lower plate layer 184 and may be electrically connected to the lower plate layer 184. In an embodiment of the present inventive concept, the lower electrode 181 may have a vertical cylindrical shape. In an embodiment of the present inventive concept, the lower electrode 181 may have a truncated cone shape. In an embodiment of the present inventive concept, the lower electrode 181 may include a metal nitride film, a metal oxide film, a metal oxynitride film, or a combination thereof. In an embodiment of the present inventive concept, the lower electrode 181 may include TiN, CoN, NbN, SnO₂, or a combination thereof.

The dielectric film 182 may conformally extend along the lower electrode 181. In an embodiment of the present inventive concept, since the dielectric film 182 conformally extends along the lower electrode 181, the dielectric film 182 may also have a vertical cylindrical shape. In an embodiment of the present inventive concept, the dielectric film 182 may have a truncated cone shape. In an embodiment of the present inventive concept, the dielectric film 182 may include a metal oxide film. In an embodiment of the present inventive concept, the dielectric film 182 may include AlO₂, ZrO₂, HfO₂, Nb₂O₅, CeO₂, TiO₂, or a combination thereof. In an embodiment of the present inventive concept, the dielectric film 182 may include a multi-layered film in which AlO₂ and ZrO₂ are alternately stacked on each other.

The upper electrode 183 may conformally extend along the dielectric film 182. The upper electrode 183 may contact the conductive interconnection member 185 and be electrically connected to the conductive interconnection member 185. In an embodiment of the present inventive concept, since the upper electrode 183 conformally extends along the dielectric film 182, the upper electrode 183 may also have a vertical cylindrical shape. In an embodiment of the present inventive concept, the upper electrode 183 may have a truncated cone shape. In an embodiment of the present inventive concept, the upper electrode 183 may include a metal nitride film, a metal oxide film, a metal oxynitride film, or a combination thereof. In an embodiment of the present inventive concept, the upper electrode 183 may include TiN, CoN, NbN, SnO₂, or a combination thereof.

The conductive interconnection member 185 may be disposed between the capacitor structure 188 and the upper plate layer 186, and may be electrically connected to the capacitor structure 188 and the upper plate layer 186. The conductive interconnection member 185 includes a first region and a second region. The first region may include buried plugs 185A that fill the through-holes 187H and are disposed on the capacitor structure 188. The second region may be disposed on an upper surface 188U of the capacitor structure 188 extending in the horizontal direction on the buried-plugs 185A and on the insulating layer 187, and may include a plate member 185B electrically connecting the buried plugs 185A to the upper plate layer 186. The buried plugs 185A and the plate member 185B of the conductive interconnection member 185 may be made of one material to be integrally formed. For example, the buried plugs 185A and the plate member 185B of the conductive interconnection member 185 may form a single body. In an embodiment of the present inventive concept, the conductive interconnect member 185 may include aluminum.

The upper plate layer 186 may be disposed on the conductive interconnect member 185 and electrically connected to the conductive interconnect member 185. In an embodiment of the present inventive concept, the upper plate layer 186 may include TiN.

The insulating layer 187 is disposed between the lower plate layer 184 and the upper plate layer 186 to at least partially surround an outer surface of the capacitor structure 188. In an embodiment of the present inventive concept, the insulating layer 187 may include SiO₂, SiOC, SiOH, SiOCH, or a low-k dielectric layer.

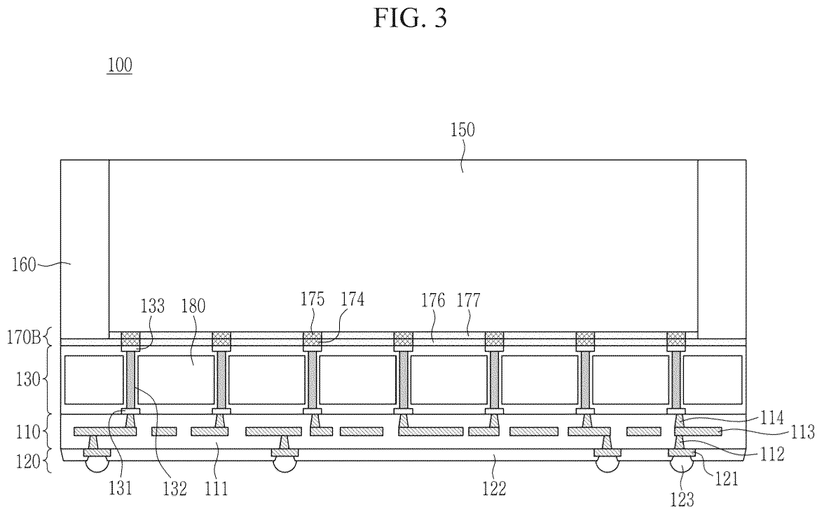

FIG. 3 illustrates a cross-sectional view of the 3D IC structure 100 that includes the first semiconductor die 130, which includes the ISC chips 180 and the TSV 132, and the second semiconductor die 150 disposed on the first semiconductor die 130. In the 3D IC structure 100, the first semiconductor die 130 and the second semiconductor die 150 are electrically and physically connected to each other by hybrid bonding.

Referring to FIG. 3, the 3D IC structure 100 may include the redistribution structure 110, the first semiconductor die 130, the second semiconductor die 150, the molding material 160, an interconnection structure 170B, and the external connection structure 120. The descriptions of the redistribution structure 110, the first semiconductor die 130, the second semiconductor die 150, the molding material 160, and the external connection structure 120 may be the same or substantially the same as those of the corresponding elements described in the description of the 3D IC structure 100 of FIG. 1.

The first semiconductor die 130 and the second semiconductor die 150 of the 3D IC structure 100 may be bonded to each other by using hybrid bonding. The hybrid bonding is a method of bonding two devices to each other by fusing the same materials of the two devices to each other by using the bonding properties of the same material. Here, hybrid means that two different types of bonding are performed, for example, bonding two devices to each other with a first type of metal-metal bonding and a second type of non-metal-non-metal bonding. According to the hybrid bonding, I/O having a fine pitch may be formed.

The interconnection structure 170B may include first bonding pads 174 and a first silicon insulating layer 176 that are disposed on the upper surface of the first semiconductor die 130. The interconnection structure 170B may further include second bonding pads 175 and a second silicon insulating layer 177 that are disposed on the lower surface of the second semiconductor die 150. The first bonding pad 174 is bonded to the second bonding pad 175, and the first silicon insulating layer 176 is bonded to the second silicon insulating layer 177. For example, the first bonding pad 174 is directly bonded to the second bonding pad 175 by metal-metal hybrid bonding, and the first silicon insulating layer 176 is directly bonded to the second silicon insulating layer 177 by non-metal-non-metal hybrid bonding.

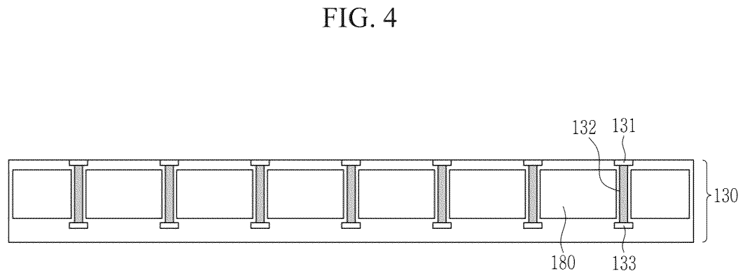

FIG. 4 illustrates a cross-sectional view of a step of providing the first semiconductor die 130 including the ISC chips 180 and the TSVs 132, in a manufacturing method of the 3D IC structure 100 according to an embodiment of the present inventive concept.

Referring to FIG. 4, the first semiconductor die 130 formed with the ISC chips 180, the lower connection pads 131, the TSVs 132, and the upper connection pads 133 is provided. The lower connection pads 131 are disposed at a front side of the first semiconductor die 130, and the upper connection pads 133 are disposed at a back side of the first semiconductor die 130.

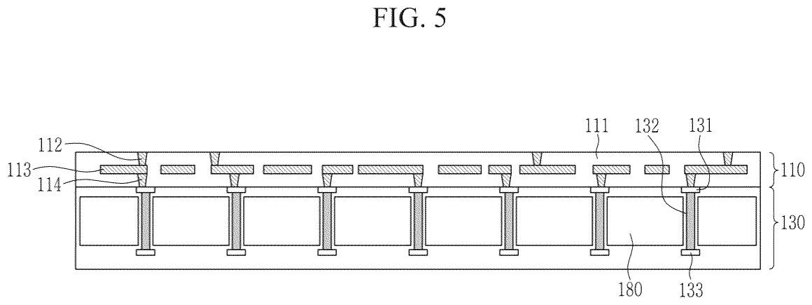

FIG. 5 illustrates a cross-sectional view of a step of forming the redistribution structure 110 on the first semiconductor die 130, in the manufacturing method of the 3D IC structure 100 according to an embodiment of the present inventive concept.

Referring to FIG. 5, the redistribution structure 110 is formed on the front side of the first semiconductor die 130.

First, the dielectric material layer 111 is formed on the front side of the first semiconductor die 130. For example, the dielectric material layer 111 may be directly disposed on the first semiconductor die 130. Since the dielectric material layer 111 is directly formed on the first semiconductor die 130, connection members such as micro-bumps and solder bumps are not used. In an embodiment of the present inventive concept, the dielectric material layer 111 may include a photosensitive polymer layer. The photosensitive polymer is a material that may form fine patterns by applying a photolithography process. In the present embodiment, the dielectric material layer 111 may include a photoimageable dielectric (PID) used in a redistribution process. As an example, the PID may include a polyimide-based photosensitive polymer, a novolak-based photosensitive polymer, polybenzoxazole, a silicon-based polymer, an acrylate-based polymer, or an epoxy-based polymer. In an embodiment of the present inventive concept, the dielectric material layer 111 is formed of a polymer such as a PBO, a polyimide, or the like. In some embodiments of the present inventive concept, the dielectric material layer 111 is formed of an inorganic dielectric material such as a silicon nitride, a silicon oxide, or the like. In an embodiment of the present inventive concept, the dielectric material layer 111 may be formed by a CVD, ALD, or PECVD process.

After forming the dielectric material layer 111, the dielectric material layer 111 may be selectively etched to form the via holes, and the via holes may be filled with a conductive material to form the redistribution vias 114. In a subsequent process, since a final product is manufactured by overturning the first semiconductor die 130 on which the redistribution structure 110 is formed, a width of an uppermost portion of each of the second redistribution vias 114 is larger than that of a lowermost portion thereof. Therefore, in the final product, the width of the uppermost portion of each of the second redistribution vias 114 is smaller than that of the lowermost portion thereof.

Next, the dielectric layer 111 is additionally deposited on the second redistribution vias 114 and the dielectric layer 111, and the additionally deposited dielectric layer 111 is selectively etched to form openings. Further, the openings are filled with a conductive material to form the redistribution lines 113.

Next, the dielectric layer 111 is additionally deposited on the first redistribution lines 113 and the dielectric layer 111, and the additionally deposited dielectric layer 111 is selectively etched to form via holes. Further, the via holes are filled with a conductive material to form the redistribution vias 112. For the same reason as the second redistribution vias 114, in the final product, a width of an uppermost portion of each first redistribution via 112 among the first redistribution vias 112 is smaller than that of a lowermost portion thereof.

In the embodiment, the first redistribution vias 112, the first redistribution lines 113, and the second redistribution vias 114 may include, for example, at least one of copper, aluminum, tungsten, nickel, gold, tin, titanium, an alloy thereof, and the like. In the embodiment, the first redistribution vias 112, the first redistribution lines 113, and the second redistribution vias 114 may be formed by, for example, performing a sputtering process. In an embodiment of the present inventive concept, the first redistribution vias 112, the first redistribution lines 113, and the second redistribution vias 114 may be formed by, for example, performing an electroplating process after forming a seed metal layer.

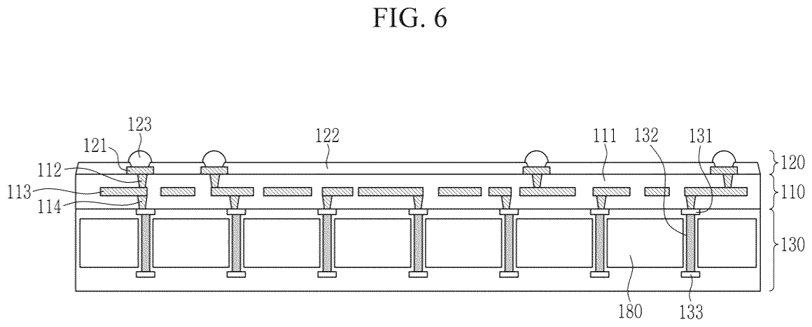

FIG. 6 illustrates a cross-sectional view of a step of forming the external connection structure 120 on the redistribution structure 110, in the manufacturing method of the 3D IC structure 100 according to an embodiment of the present inventive concept.

Referring to FIG. 6, the external connection structure 120 is formed on the redistribution structure 110. The insulating layer 122 may be formed on the dielectric layer 111 of the redistribution structure 110, and the conductive pads 121 may be formed on the first redistribution vias 112. In the embodiment, the conductive pad 121 may include, for example, at least one of copper, nickel, zinc, gold, silver, platinum, palladium, chromium, titanium, and an alloy thereof. In the embodiment, the insulating layer 122 may include a solder resist. In the embodiment, the external connection member 123 may include, for example, at least one of tin, silver, lead, nickel, copper, and an alloy thereof. In the embodiment, the conductive pad 121 may be formed, for example, by performing a sputtering process, or by performing an electroplating process after forming a seed metal layer. In the embodiment, the insulating layer 122 may be formed by, for example, a CVD, ALD, or PECVD process.

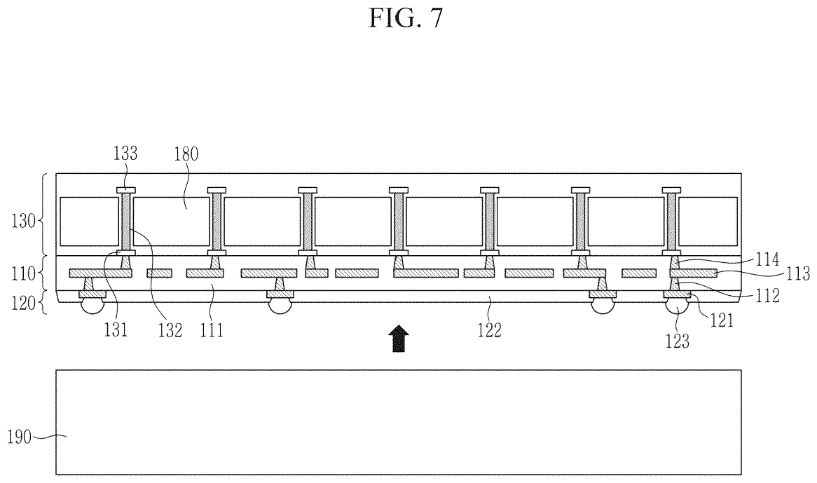

FIG. 7 illustrates a cross-sectional view of a step of bonding a carrier 190 under the external connection structure 120, in the manufacturing method of the 3D IC structure 100 according to an embodiment of the present inventive concept.

Referring to FIG. 7, the first semiconductor die 130 on which the external connection structure 120 is formed is reversed and aligned, and the carrier 190 is bonded under the external connection structure 120. The carrier 190 may include, for example, a silicon-based material such as glass or a silicon oxide, an organic material, or another material such as an aluminum oxide, a combination of these materials, and the like.

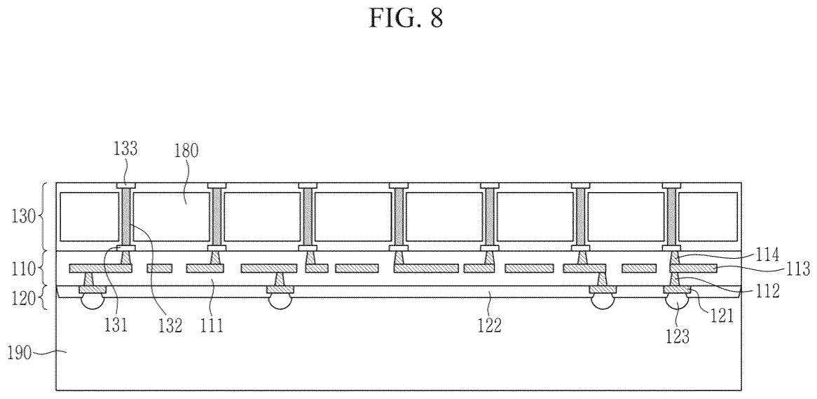

FIG. 8 illustrates a cross-sectional view of a step of removing an upper surface (e.g., a back side) of the first semiconductor die 130, in the manufacturing method of the 3D IC structure 100 according to an embodiment of the present inventive concept.

Referring to FIG. 8, the back side of the first semiconductor die 130 is removed by grinding, and the upper connection pads 133 of the first semiconductor die 130 are exposed.

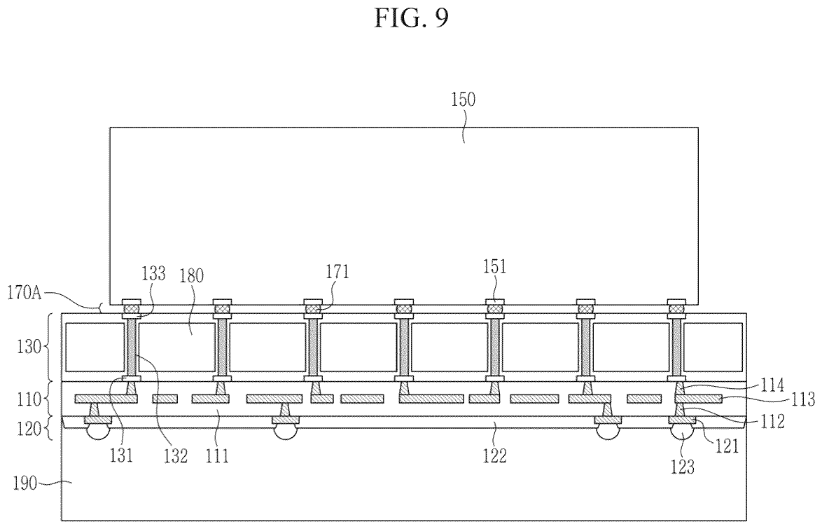

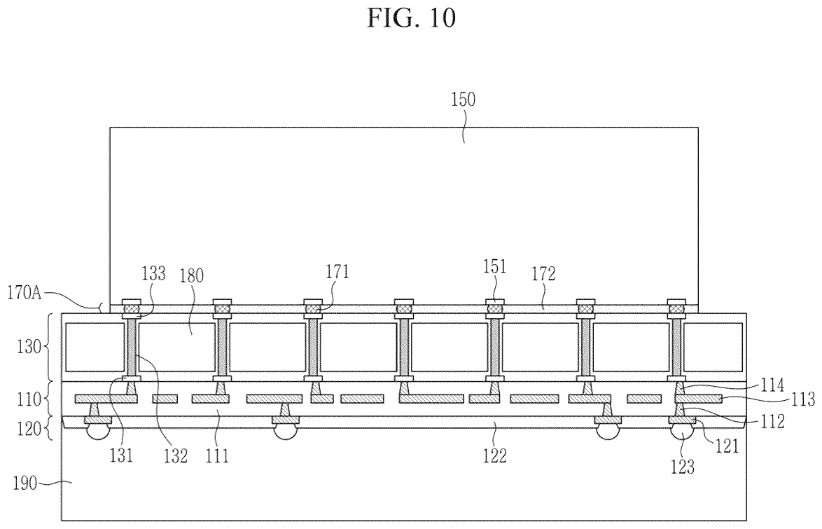

FIG. 9 illustrates a cross-sectional view of a step of mounting the second semiconductor die 150 on the first semiconductor die 130 by flip-chip bonding, in the manufacturing method of the 3D IC structure 100 according to an embodiment of the present inventive concept. FIG. 9 and FIG. 10 illustrate cross-sectional views of steps in the manufacturing method of the 3D IC structure 100 shown in FIG. 1 according to an embodiment of the present inventive concept.

Referring to FIG. 9, the second semiconductor die 150 is mounted on the first semiconductor die 130 by using the connection member 171. The upper connection pad 133 of the first semiconductor die 130 and the connection pad 151 of the second semiconductor die 150 are electrically connected to each other by using the connection member 171. In the embodiment, the connection member 171 may include micro-bumps. In the embodiment, the connection member 171 may include, for example, at least one of tin, silver, lead, nickel, copper, and an alloy thereof.

FIG. 10 illustrates a cross-sectional view of a step of forming the insulating member 172 between the first semiconductor die 130 and the second semiconductor die 150, in the manufacturing method of the 3D IC structure according to an embodiment of the present inventive concept.

Referring to FIG. 10, the insulating member 172 is disposed between the first semiconductor die 130 and the second semiconductor die 150 to at least partially surround the connection members 171. As described above, stress between the first semiconductor die 130 and the second semiconductor die 150 may be alleviated by disposing the insulating member 172 between the first semiconductor die 130 and the second semiconductor die 150.

In the embodiment, before mounting the second semiconductor die 150 on the first semiconductor die 130, a non-conductive film (NCF) may be attached to the first semiconductor die 130 as the insulating member 172. The non-conductive film NCF has adhesiveness and is attached on the first semiconductor die 130. The non-conductive film (NCF) has an uncured state that may be deformed by an external force. The non-conductive film (NCF) may be attached by heating at a temperature of about 170° C. to about 300° C. for about 1 second to about 20 seconds. Then, the second semiconductor die 150 is stacked on the non-conductive film (NCF). The connection member 171, which is provided on the second semiconductor die 150, may pass through the non-conductive film (NCF) to contact the upper connection pad 133 of the first semiconductor die 130.

In an embodiment of the present inventive concept, after the second semiconductor die 150 is bonded to the first semiconductor die 130 by using the connection member 171, a molded under-fill (MUF) may fill a space between the first semiconductor die 130 and the second semiconductor die 150.

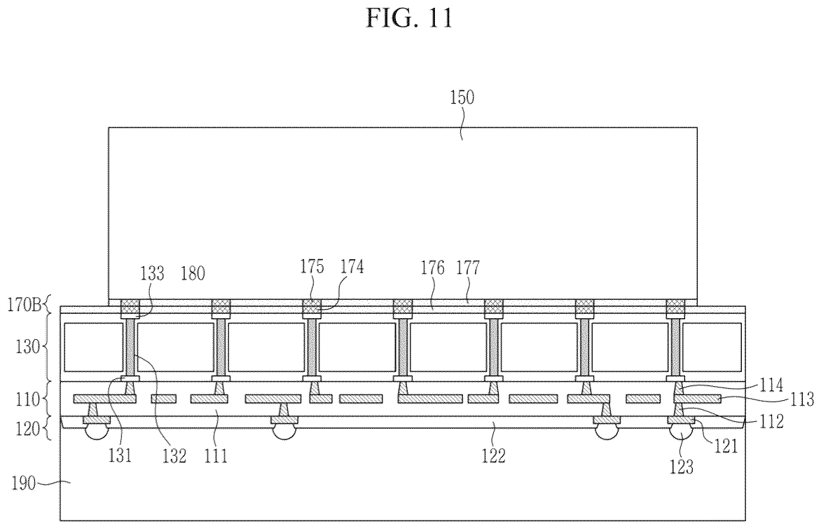

FIG. 11 illustrates a cross-sectional view of a step of mounting the second semiconductor die 150 on the first semiconductor die 130 by hybrid bonding, in the manufacturing method of the 3D IC structure 100 according to an embodiment of the present inventive concept. FIG. 11 illustrates a cross-sectional view of steps of the manufacturing method of the 3D IC structure 100 of FIG. 3 according to an embodiment of the present inventive concept.

Referring to FIG. 11, hybrid bonding is performed to bond the first semiconductor die 130 and the second semiconductor die 150 to each other. The first bonding pad 174, which is disposed on the upper surface of the first semiconductor die 130, and the second bonding pad 175, which is disposed on the lower surface of the second semiconductor die 150, may be bonded to each other by metal-metal hybrid bonding. For example, the first bonding pad 174, which is disposed on the upper surface of the first semiconductor die 130, and the second bonding pad 175, which is disposed on the lower surface of the second semiconductor die 150, may be directly bonded to each other by metal-metal hybrid bonding. Metal bonding may be performed at an interface between the first bonding pad 174, which is disposed on the upper surface of the first semiconductor die 130, and the second bonding pad 175, which is disposed on the lower surface of the second semiconductor die 150, by the metal-metal hybrid bonding. In the embodiment, the first bonding pad 174 and the second bonding pad 175 may include, for example, copper. In an embodiment of the present inventive concept, the first bonding pad 174 and the second bonding pad 175 may include metallic materials to which hybrid bonding may be applied.

The first bonding pad 174, which is disposed on the upper surface of the first semiconductor die 130, and the second bonding pad 175, which is disposed on the lower surface of the second semiconductor die 150, are made of the same material, so that after hybrid bonding, an interface between the first bonding pad 174, which is disposed on the upper surface of the first semiconductor die 130, and the second bonding pad 175, which is disposed on the lower surface of the second semiconductor die 150, may be eliminated. The first semiconductor die 130 and the second semiconductor die 150 may be electrically connected to each other through the first bonding pad 174 and the second bonding pad 175.

The first silicon insulating layer 176, which is disposed on the upper surface of the first semiconductor die 130, and the second silicon insulating layer 177, which is disposed on the lower surface of the second semiconductor die 150, may be bonded to each other by non-metal-non-metal hybrid bonding. For example, the first silicon insulating layer 176, which is disposed on the upper surface of the first semiconductor die 130, and the second silicon insulating layer 177, which is disposed on the lower surface of the second semiconductor die 150, may be directly bonded to each other by non-metal-non-metal hybrid bonding. A covalent bond is made at the interface between the first silicon insulating layer 176, which is disposed on the upper surface of the first semiconductor die 130, and the second silicon insulating layer 177, which is disposed on the lower surface of the second semiconductor die 150, by non-metal-non-metal hybrid bonding.

In the embodiment, the first silicon insulating layer 176 and the second silicon insulating layer 177 may include, for example, a silicon oxide or a TEOS forming oxide. In the embodiment, the first silicon insulating layer 176 and the second silicon insulating layer 177 may include, for example, SiO₂. In an embodiment of the present inventive concept, the first silicon insulating layer 176 and the second silicon insulating layer 177 may include a silicon nitride, a silicon oxynitride, or other suitable dielectric material. In an embodiment of the present inventive concept, the first silicon insulating layer 176 and the second silicon insulating layer 177 may include SiN or SiCN.

The first silicon insulating layer 176, which is disposed on the upper surface of the first semiconductor die 130, and the second silicon insulating layer 177, which is disposed on the lower surface of the second semiconductor die 150, are made of the same material, so that after hybrid bonding, an interface between the first silicon insulating layer 176 and the second silicon insulating layer 177 may be eliminated.

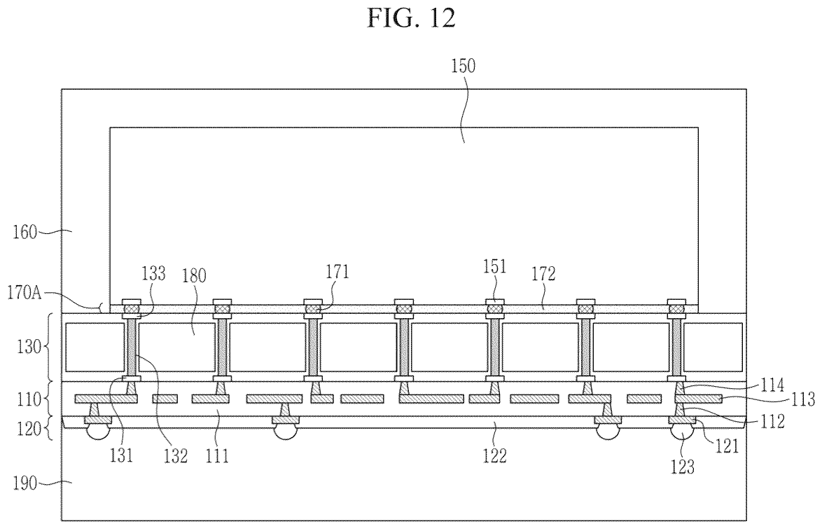

FIG. 12 illustrates a cross-sectional view of a step of molding the second semiconductor die 150 on the first semiconductor die 130, in the manufacturing method of the 3D IC structure 100 according to an embodiment of the present inventive concept.

Referring to FIG. 12, on the first semiconductor die 130, the second semiconductor die 150 is molded with the molding material 160. In some embodiments of the present inventive concept, the process of molding with the molding material 160 may include a compression molding or transfer molding process.

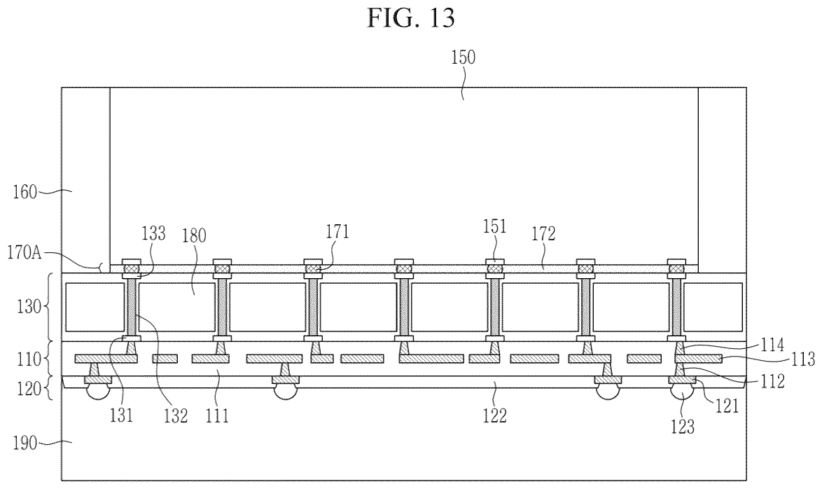

FIG. 13 illustrates a cross-sectional view of a step of planarizing the molding material 160, in the manufacturing method of the 3D IC structure 100 according to an embodiment of the present inventive concept.

Referring to FIG. 13, chemical mechanical polishing (CMP) is performed to level an upper surface of the molding material 160. The upper surface of the molding material 160 is planarized by applying a CMP process. For example, an upper portion of the molding material 160 may be removed to expose an upper surface of the second semiconductor die 150, and the upper surface of the molding material 160 may be coplanar with the upper surface of the second semiconductor die 150.

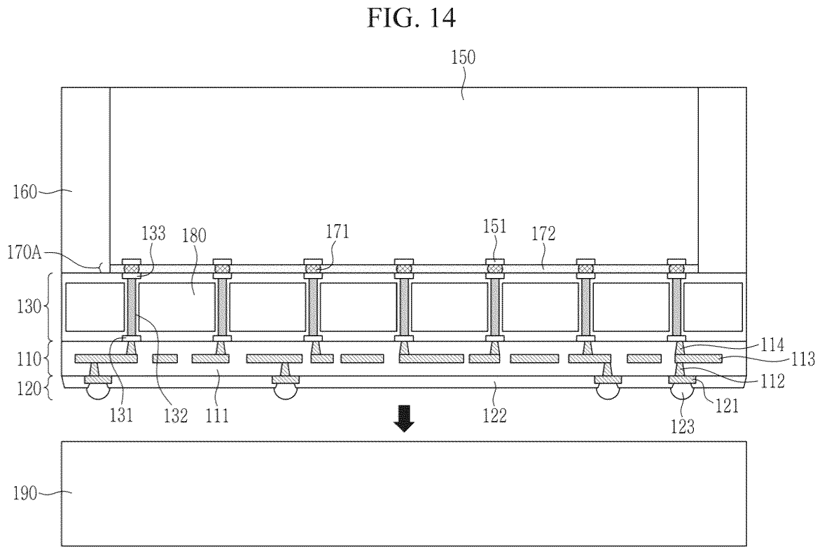

FIG. 14 illustrates a cross-sectional view of a step of de-bonding the carrier from the external connection structure 120, in the manufacturing method of the 3D IC structure 100 according to an embodiment of the present inventive concept.

Referring to FIG. 14, the carrier 190 is removed from the external connection structure 120.

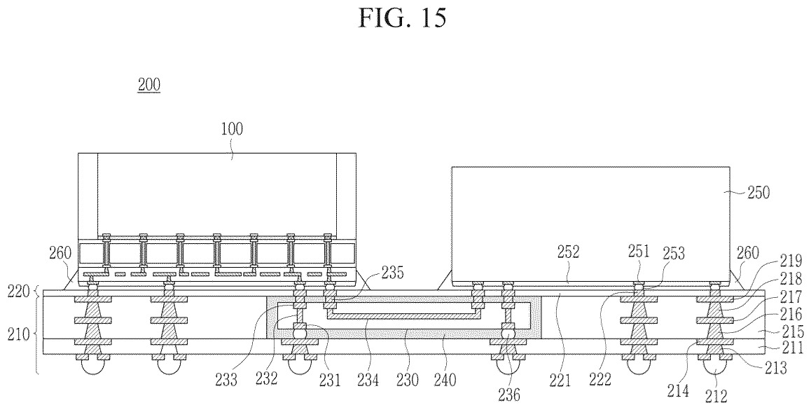

FIG. 15 illustrates a cross-sectional view of a semiconductor package 200 that includes the 3D IC structure 100 according to an embodiment of the present inventive concept. The 3D IC structure 100 includes the first semiconductor die 130, which includes the ISC chips 180 and the TSVs 132, and the second semiconductor die 150 that is disposed on the first semiconductor die 130. The semiconductor package 200 additionally includes a semiconductor structure 250, and the 3D IC structure 100 and the semiconductor structure 250 are connected to each other by a bridge structure 230.

Referring to FIG. 15, the semiconductor package 200 may include a substrate 210, a connection structure 220, the bridge structure 230, a molding material 240, the 3D IC structure 100, and the semiconductor structure 250.

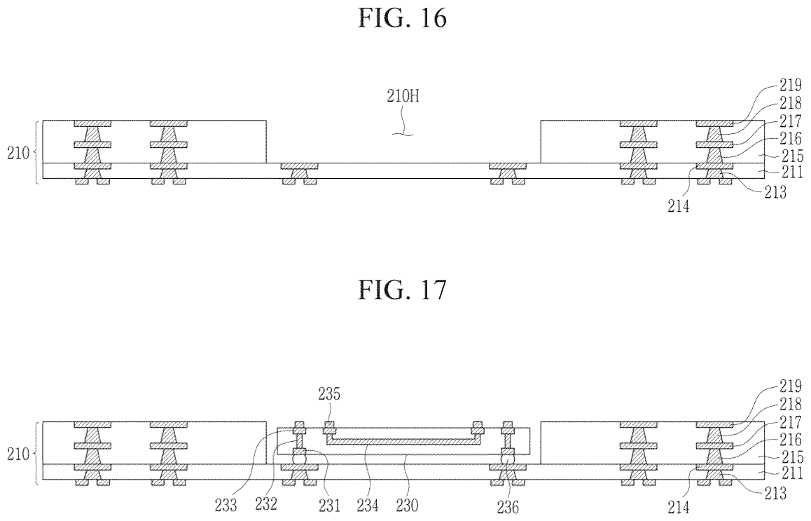

The substrate 210 may include a first insulating layer 211, an external connection member 212, a connection pad 213, a first wire layer 214, a second insulating layer 215, a first via 216, a second wire layer 217, a second via 218, and a third wire layer 219. In the embodiment, the substrate 210 may include a printed circuit board. In the embodiment, the substrate 210 may include an embedded trace substrate (ETS) having a coreless form in which a core layer is removed. In the embodiment, the substrate 210 may include a cavity 210H (see FIG. 16) therein. In some embodiments of the present inventive concept, substrates including fewer or greater numbers of insulating layers, wire layers, vias, external connection members, and connection pads are within the scope of the present inventive concept.

In the embodiment, the connection pad 213, the first wire layer 214, the second insulating layer 215, the first via 216, the second wire layer 217, the second via 218, and the third wire layer 219 may each include, for example, at least one of copper, nickel, zinc, gold, silver, platinum, palladium, chromium, titanium, and an alloy thereof. In the embodiment, the first insulating layer 211 may include a solder resist. In the embodiment, the second insulating layer 215 may include, for example, at least one of a thermosetting epoxy resin, and a resin including a filler. In the embodiment, the external connection member 212 may include, for example, at least one of tin, silver, lead, nickel, copper, and an alloy thereof.

The connection structure 220 may include a third insulating layer 221 and a connection member 222. The third insulating layer 221 and the connection member 222 may be disposed on the substrate 210 and the bridge structure 230. The third insulating layer 221 may at least partially surround and protect the connection member 222. In the embodiment, the third insulating layer 221 may include a solder resist. The third connection member 222 may electrically connect the substrate 210 and the 3D IC structure 100 to each other, the bridge structure 230 and the 3D IC structure 100 to each other, the substrate 210 and the semiconductor structure 250 to each other, and the bridge structure 230 and the semiconductor structure 250 to each other. In the embodiment, the connection member 222 may include, for example, at least one of copper, nickel, zinc, gold, silver, platinum, palladium, chromium, titanium, and an alloy thereof.

The bridge structure 230 may include lower conductive pads 231, TSVs 232, upper conductive pads 233, conductive lines 234, connection members 235, and connection members 236. The bridge structure 230 may be disposed within the cavity 210H of the substrate 210. In the embodiment, the 3D IC structure 100 may be disposed on a portion of an upper surface of the bridge structure 230, and the semiconductor structure 250 may be disposed on another portion of the upper surface of the bridge structure 230. In the embodiment, the bridge structure 230 may include, for example, a silicon bridge. The TSVs 232 included in the bridge structure 230 may vertically and rapidly move data, and may reduce power consumption, thereby increasing performance of a semiconductor package.

The TSV 232 may be disposed between some of the upper conductive pads 233 and the lower conductive pad 231, and may electrically connect the connection pad 213 and the 3D IC structure 100 to each other. In addition, the TSV 232 may electrically connect the connection pad 213 and the semiconductor structure 250 to each other in the vertical direction. The conductive line 234 may be disposed between some of the upper conductive pads 233, and may electrically connect the 3D IC structure 100 to the semiconductor structure 250 in the horizontal direction. The connection member 235 may be disposed between the upper conductive pad 233 and the connection member 222, and may electrically connect the upper conductive pad 233 and the connection member 222 to each other. The connection member 236 may be disposed between the lower conductive pad 231 and the connection pad 213, and may electrically connect the lower conductive pad 231 and the connection pad 213 to each other.

In the embodiment, the TSV 232 and the conductive line 234 may each include, for example, at least one of tungsten, aluminum, copper, and an alloy thereof. In the embodiment, the lower connection pad 231, the upper connection pad 233, the connection member 235, and the connection member 236 may each include, for example, at least one of copper, aluminum, silver, tin, gold, nickel, lead, titanium, and an alloy thereof.

The molding material 240 molds the bridge structure 230 within the cavity 210H of the substrate 210. For example, the molding material 240 may at least partially surround the bridge structure 230. In the embodiment, the molding material 240 may be formed of a thermosetting resin such as epoxy resin. In an embodiment of the present inventive concept, the molding material 240 may be an epoxy molding compound (EMC).

The contents shown and described in FIG. 1 and FIG. 3 may be equally applied to the 3D IC structure 100. An under-fill material 260 may be applied to the lower surface and at least a portion of the side surface of the 3D IC structure 100, and the under-fill material 260 may at least partially surround the external connection members 123 of the 3D IC structure 100.

The semiconductor structure 250 may be disposed side by side with the 3D IC structure 100 at an upper portion of the connection structure 220. In the embodiment, the semiconductor structure 250 may include, for example, a DRAM or a high bandwidth memory (HBM). The semiconductor structure 250 may include conductive pads 251, an insulating layer 252, and external connection members 253. The conductive pad 251 may be electrically connected to the external connection member 253. The insulating layer 252 may include a plurality of openings for soldering. The insulating layer 252 may prevent the external connection member 253 from being short-circuited. The external connection member 253 may be disposed in an opening of the insulating layer 252, and may electrically connect the semiconductor structure 250 to the connection structure 220. The under-fill material 260 may be applied to a lower surface and at least a portion of a side surface of the semiconductor structure 250, and the under-fill material 260 may at least partially surround the external connection members 253 of the semiconductor structure 250.

FIG. 16 illustrates a cross-sectional view of a step of providing the substrate 210 including the cavity 210H, in the manufacturing method of the semiconductor package 200 according to an embodiment of the present inventive concept.

Referring to FIG. 16, the substrate 210 including the cavity 210H is provided.

FIG. 17 illustrates a cross-sectional view of a step of mounting the bridge structure 230 in the cavity 210H of the substrate 210, in the manufacturing method of the semiconductor package 200 according to an embodiment of the present inventive concept.

Referring to FIG. 17, the bridge structure 230 is mounted in the cavity 210H of the substrate 210.

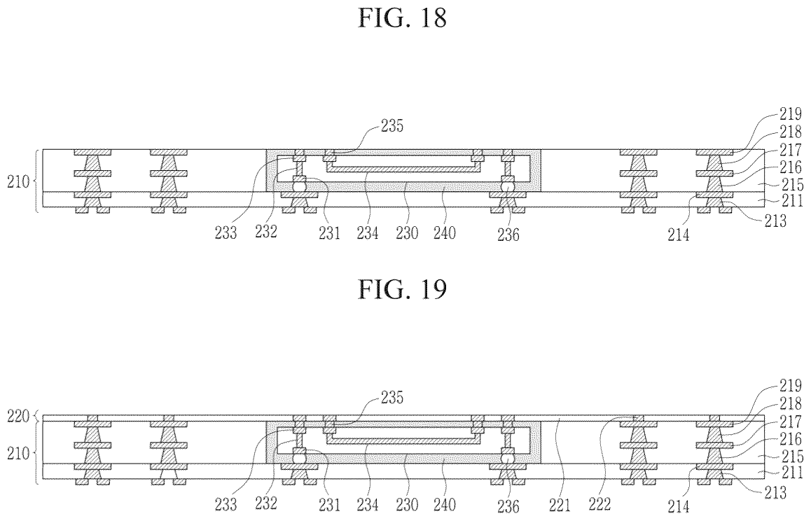

FIG. 18 illustrates a cross-sectional view of a step of molding the bridge structure 230 in the cavity 210H of the substrate 210, in the manufacturing method of the semiconductor package 200 according to an embodiment of the present inventive concept.

Referring to FIG. 18, the bridge structure 230, which is disposed in the cavity 210H of the substrate 210, is molded by the molding material 240. In the embodiment, the process of molding with the molding material 240 may include a compression molding or transfer molding process.

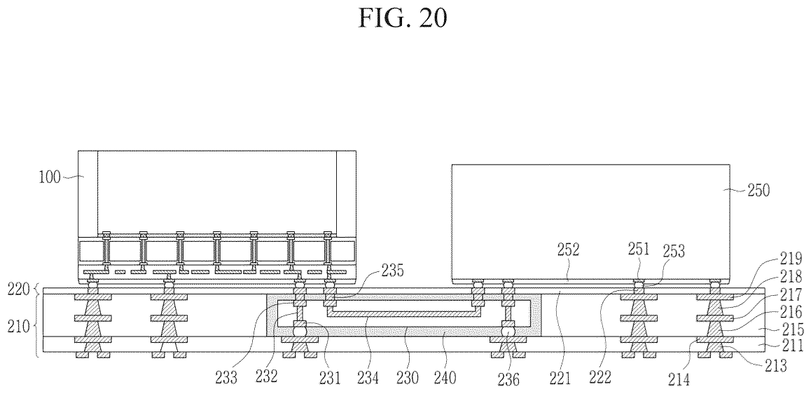

FIG. 19 illustrates a cross-sectional view of a step of forming the connection structure 220 on the substrate 210 and the molding material 240, in the manufacturing method of the semiconductor package 200 according to an embodiment of the present inventive concept.

Referring to FIG. 19, the third insulating layer 221 and the connection member 222 are formed on the substrate 210 and the molding material 240. In the embodiment, the third insulating layer 221 may be formed by, for example, a CVD, ALD, or PECVD process. In the embodiment, the connection member 222 may be formed by, for example, performing a sputtering process, or by performing an electroplating process after forming a seed metal layer.

FIG. 20 illustrates a cross-sectional view of a step of mounting the 3D IC structure 100 and the semiconductor structure 250 on the connection structure 220, in the manufacturing method of the semiconductor package 200 according to an embodiment of the present inventive concept.

Referring to FIG. 20, the 3D IC structure 100 and the semiconductor structure 250 are mounted on the connection structure 220.

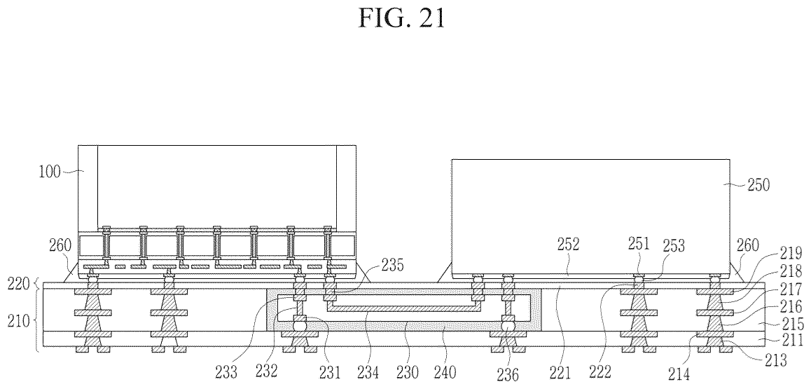

FIG. 21 illustrates a cross-sectional view of a step of under-filling the 3D IC structure 100 and the semiconductor structure 250 on the connection structure 220, in the manufacturing method of the semiconductor package 200 according to an embodiment of the present inventive concept.

Referring to FIG. 21, the under-fill material 260 may be applied to the lower surface and at least a portion of the side surface of the semiconductor structure 250. In the embodiment, the under-fill material 260 may include, for example, a molded under-fill (MUF).

While the present inventive concept has been shown and described with reference to the embodiments thereof, it will be apparent to those of ordinary skill in the art that various changes in form and detail may be made thereto without departing from the spirit and scope of the present inventive concept.

What is claimed is:

1. A three-dimensional integrated circuit structure, comprising:
a first semiconductor die; and
a second semiconductor die disposed on the first semiconductor die,
wherein the first semiconductor die includes:
a plurality of through-silicon vias (TSV); and
a plurality of integrated stack capacitor (ISC) chips, wherein each of the plurality of ISC chips is disposed between adjacent through-silicon vias among the plurality of through-silicon vias.

2. The three-dimensional integrated circuit structure of claim 1, wherein
the integrated stack capacitor chip includes:
a lower plate layer;
an insulating layer disposed on the lower plate layer and including a plurality of through-holes;
a lower electrode continuously and conformally extending along an inside of the plurality of through-holes and along the insulating layer;
a dielectric film disposed on the lower electrode;
an upper electrode disposed on the dielectric film;
a conductive interconnection member disposed on the upper electrode; and
an upper plate layer disposed on the conductive interconnection member.

3. The three-dimensional integrated circuit structure of claim 1, wherein
the plurality of through-silicon vias is alternately arranged with the plurality of integrated stacked capacitor chips.

4. The three-dimensional integrated circuit structure of claim 1, wherein
a distance between a through-silicon via of the plurality of through-silicon vias and an integrated stack capacitor chip, of the plurality of integrated stack capacitor chip, adjacent to the through-silicon via is smaller than a width of each through-silicon via of the plurality of through-silicon vias in a horizontal direction.

5. The three-dimensional integrated circuit structure of claim 1, wherein
the second semiconductor die includes a system on chip (SOC).

6. The three-dimensional integrated circuit structure of claim 1, further comprising
a molding material disposed on the second semiconductor die and on the first semiconductor die.

7. A three-dimensional integrated circuit structure, comprising:
a redistribution structure;
a first semiconductor die disposed on the redistribution structure;
an interconnection structures disposed on the first semiconductor die; and
a second semiconductor die disposed on the interconnection structure,
wherein the first semiconductor die includes:
a plurality of through-silicon vias (TSV); and
a plurality of integrated stack capacitor (ISC) chips, wherein each of the plurality of integrated stack capacitor chips is disposed between neighboring through-silicon vias among the plurality of through-silicon vias.

8. The three-dimensional integrated circuit structure of claim 7, wherein
the redistribution structure includes a plurality of redistribution vias, and
an uppermost width of each of the plurality of redistribution vias is smaller than a lowermost width thereof.

9. The three-dimensional integrated circuit structure of claim 7, wherein
the interconnection structure includes a connection member.

10. The three-dimensional integrated circuit structure of claim 9, wherein
the connection member includes a micro bump.

11. The three-dimensional integrated circuit structure of claim 9, wherein
the interconnection structure further includes an insulating member at least partially surrounding the connection member.

12. The three-dimensional integrated circuit structure of claim 11, wherein
the insulating member includes a non-conductive film (NCF).

13. The three-dimensional integrated circuit structure of claim 7, wherein
the interconnection structure includes a plurality of first bonding pads and a first silicon insulating layer disposed on an upper surface of the first semiconductor die, and
the interconnection structure includes a plurality of second bonding pads and a second silicon insulating layer disposed on a lower surface of the second semiconductor die.

14. The three-dimensional integrated circuit structure of claim 13, wherein
the plurality of first bonding pads is respectively bonded to the plurality of second bonding pads.

15. The three-dimensional integrated circuit structure of claim 13, wherein
the first silicon insulating layer is bonded to the second silicon insulating layer.

16. A semiconductor package comprising:
a substrate;
a three-dimensional integrated circuit structure disposed on the substrate;
a semiconductor structure disposed adjacent to the three-dimensional integrated circuit structure on the substrate; and
a bridge structure disposed in the substrate and electrically connecting the three-dimensional integrated circuit structure and the semiconductor structure to each other,
wherein the three-dimensional integrated circuit structure includes:
a first semiconductor die; and
a second semiconductor die disposed on the first semiconductor die,
wherein the first semiconductor die includes:
a plurality of through-silicon vias (TSV); and
a plurality of integrated stack capacitor (ISC) chips, wherein each of the plurality of integrated stack capacitor chips is disposed between adjacent through-silicon vias among the plurality of through-silicon vias.

17. The semiconductor package of claim 16, wherein
the three-dimensional integrated circuit structure is disposed on a portion of the bridge structure, and the semiconductor structure is disposed on another portion of the bridge structure.

18. The semiconductor package of claim 16, wherein
the bridge structure includes a silicon bridge.

19. The semiconductor package of claim 16, wherein
the semiconductor structure includes a high-bandwidth memory (HBM) semiconductor.

20. The semiconductor package of claim 16, wherein
the substrate includes an embedded trace substrate (ETS).
